(19) United States
(12) Patent Application Publication
(10) Pub. No.: US 2026/0269789 A1
(43) Pub. Date: Sep. 10, 2026

(54) DOHERTY AMPLIFIER

(71) Applicant: Murata Manufacturing Co., Ltd., Nagaokakyo-shi (JP)

(72) Inventors: Hideyuki SATO, Nagaokakyo-shi (JP); Jun Enomoto, Nagaokakyo-shi (JP)

(21) Appl. No.: 19/659,099

(22) Filed: Apr. 27, 2026

Related U.S. Application Data
(63) Continuation of application No. PCT/JP2024/044488, filed on Dec. 16, 2024.

(30) Foreign Application Priority Data
Dec. 26, 2023 (JP) 2023-219170

(51) Int. Cl. H03F 1/02; H03F 1/22; H03F 1/30; H03F 1/56

(52) U.S. Cl. CPC H03F 1/0288; H03F 1/22; H03F 1/302; H03F 1/56; H03F 2200/451

(57) ABSTRACT

A Doherty amplifier includes a carrier amplifier and a peak amplifier. A carrier-amplifier bias circuit supplies a bias to the carrier amplifier. A peak-amplifier bias circuit supplies a bias to the peak amplifier. A draw-off circuit draws off a portion of a bias current supplied from the peak-amplifier bias circuit to the peak amplifier. The draw-off circuit includes a cascode circuit in which a common-base transistor and a common-emitter transistor are cascode-connected. The collector of the common-base transistor is connected to the peak amplifier, and the base of the common-emitter transistor is connected to the input node of the carrier amplifier.

### CROSS REFERENCE TO RELATED APPLICATION

This is a continuation of International Application No. PCT/JP2024/044488 filed on December 16, 2024 which claims priority from Japanese Patent Application No. 2023-219170 filed on December 26, 2023. The contents of these applications are incorporated herein by reference in their entireties.

### BACKGROUND OF THE DISCLOSURE

### Field of the Disclosure

The present disclosure relates to a Doherty amplifier.

### Description of the Related Art

Known Doherty amplifiers are configured to operate in two operating modes including a low-power mode and a high-power mode (see Seongjun Bae et al., "Bias-Switching Quasi-Doherty-Type Amplifier for CDMA Handset Applications", IEEE Radio Frequency Integrated Circuits Symposium Digest, pp. 137-140, 2003). Such a Doherty amplifier operates in the low-power mode at output power levels less than or equal to a given threshold, for example, 20 dBm, and operates in the high-power mode at output power levels above the threshold. A peak amplifier receives a different bias depending on whether the Doherty amplifier is operating in the low-power mode or the high-power mode. This configuration mitigates degradation of power-added efficiency (PAE) during operation in the low-power mode.

### BRIEF SUMMARY OF THE DISCLOSURE

For instance, in handling radio frequency signals with a high peak-to-average power ratio (PAPR), such as those used in cyclic prefix-orthogonal frequency division multiplexing (CP-OFDM) for fifth-generation mobile communication systems (5G), the Doherty amplifier needs to be operated in the high-power mode even when the output power is relatively low, in anticipation of high-power signal input. At this time, the gain of the peak amplifier does not become completely zero. This leads to PAE degradation.

It is a possible benefit of the present disclosure to provide a Doherty amplifier configured to mitigate PAE degradation even in amplifying a high-PAPR radio frequency signal.

An aspect of the present disclosure provides a Doherty amplifier including: a carrier amplifier; a peak amplifier; a carrier-amplifier bias circuit configured to supply a bias to the carrier amplifier; a peak-amplifier bias circuit configured to supply a bias to the peak amplifier; and a draw-off circuit configured to draw off a portion of a bias current supplied from the peak-amplifier bias circuit to the peak amplifier. The draw-off circuit includes a cascode circuit in which a common-base transistor and a common-emitter transistor are cascode-connected. A collector of the common-base transistor is connected to the peak amplifier. A base of the common-emitter transistor is connected to an input node of the carrier amplifier.

Another aspect of the present disclosure provides a Doherty amplifier including: a carrier amplifier; a peak amplifier; a carrier-amplifier bias circuit configured to supply a bias to the carrier amplifier; a peak-amplifier bias circuit configured to supply a bias to the peak amplifier; and a draw-off circuit configured to draw off, from a bias current supplied from the peak-amplifier bias circuit to the peak amplifier, a current that is dependent on an amplitude of an input current inputted to the carrier amplifier.

When an input current inputted to the input node of the carrier amplifier increases in amplitude, a current that flows in the common-emitter transistor increases due to the self-biasing effect, and a current that flows in the cascode circuit also increases. As a result, the bias current supplied to the peak amplifier decreases, which mitigates an increase in gain caused by the self-biasing effect of the peak amplifier.

Due to the mitigation of an increase in the gain of the peak amplifier, PAE degradation of the Doherty amplifier is mitigated.

### BRIEF DESCRIPTION OF THE SEVERAL VIEWS OF THE DRAWINGS

FIG. 1 is a block diagram of a Doherty amplifier according to a first embodiment.

FIG. 2 is an equivalent circuit diagram of a carrier amplifier, a peak amplifier, and a draw-off circuit of the Doherty amplifier according to the first embodiment.

FIG. 3 is an equivalent circuit diagram of a peak-amplifier bias circuit.

FIG. 4 illustrates graphs representing the relationship between output power Pout and each of gain and draw-off current, of which the top graph represents the relationship between output power Pout of the Doherty amplifier and gain, and the bottom graph represents the relationship between output power Pout of the Doherty amplifier and draw-off current Is.

FIG. 5 is a block diagram of a Doherty amplifier according to a second embodiment.

FIG. 6 is an equivalent circuit diagram of the carrier amplifier, the peak amplifier, and the draw-off circuit of the Doherty amplifier according to the second embodiment.

FIG. 7 illustrates graphs representing an example of the respective waveforms over one period of a radio frequency current Ibd, a radio frequency current Iinc1, and a radio frequency current Ioutc1 (FIG. 6), which are supplied to the base of a common-emitter transistor 30Qd.

FIG. 8 illustrates graphs representing the relationship between output power Pout and each of gain and draw-off current, of which the top graph represents the relationship between output power Pout of the Doherty amplifier and gain of the peak amplifier, and the bottom graph represents the relationship between output power Pout of the Doherty amplifier and draw-off current Is.

FIG. 9 illustrates graphs representing the relationship between gain and output power Pout, of which the top graph represents the gain when load impedance ZL is at its design value (e.g., 50 Ω), that is, when a Doherty amplifier and the load impedance ZL are impedance-matched to each other, and VSWR is 1, the middle graph represents the gain of a Doherty amplifier according to a comparative example when the load impedance ZL is higher than 50 Ω, and the bottom graph represents the gain of the Doherty amplifier according to the second embodiment when the load impedance ZL is higher than 50 Ω.

FIG. 10 is an equivalent circuit diagram of the peak amplifier and the draw-off circuit of a Doherty amplifier according to a third embodiment.

FIG. 11 is a diagram illustrating the layout of elements constituting part of the peak amplifier and draw-off circuit of the Doherty amplifier according to the third embodiment.

FIG. 12 is a diagram illustrating the layout of elements constituting part of the peak amplifier and draw-off circuit of a Doherty amplifier according to a modification of the third embodiment.

FIG. 13 is a diagram illustrating the layout of elements constituting part of the peak amplifier and draw-off circuit of a Doherty amplifier according to another modification of the third embodiment.

FIG. 14 is an equivalent circuit diagram of a Doherty amplifier according to a fourth embodiment.

### DETAILED DESCRIPTION OF THE DISCLOSURE

### (First Embodiment)

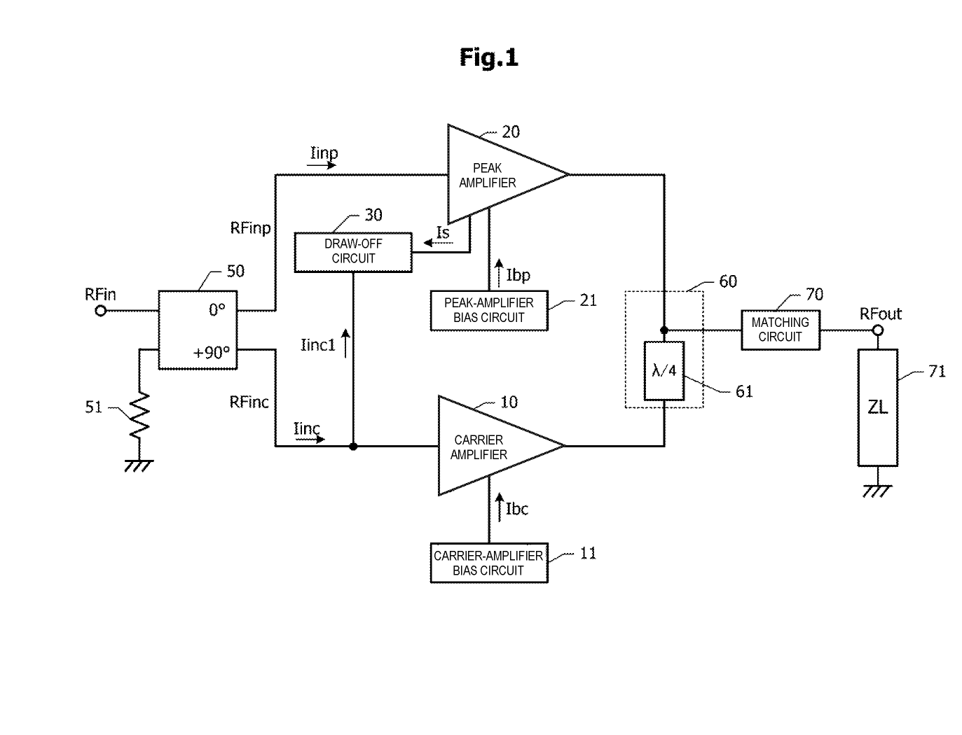

A Doherty amplifier according to a first embodiment will now be described with reference to FIGS. 1 to 4.

FIG. 1 is a block diagram of the Doherty amplifier according to the first embodiment. An input signal RFin is inputted to one input terminal of a divider 50. The other input terminal of the divider 50 is grounded via a matched termination resistor 51. The divider 50 outputs a peak-amplifier input signal RFinp from one output terminal, and outputs a carrier-amplifier input signal RFinc from the other output terminal. The carrier-amplifier input signal RFinc is advanced in phase by 90 degrees relative to the peak-amplifier input signal RFinp. The divider 50 is, for example, a 90° hybrid circuit.

The peak-amplifier input signal RFinp is inputted to a peak amplifier 20, and the carrier-amplifier input signal RFinc is inputted to a carrier amplifier 10. A peak-amplifier bias circuit 21 outputs a bias current Ibp for the peak amplifier. The bias current Ibp is set so as to operate the peak amplifier in class C. A carrier-amplifier bias circuit 11 supplies the carrier amplifier 10 with a bias current Ibc for the carrier amplifier. The bias current Ibc is set so as to operate the carrier amplifier 10 in class AB.

A draw-off circuit 30 receives input of a radio frequency current (to be referred to as radio frequency current Iinc1 hereinafter), which is a portion of a radio frequency current (to be referred to as input current Iinc hereinafter) of the carrier-amplifier input signal RFinc. The level (e.g., amplitude) of the radio frequency current Iinc1 is determined in accordance with the level of the input current Iinc, the input impedance of the carrier amplifier 10, and the input impedance of the draw-off circuit 30. Therefore, adjusting the capacitance of a capacitor 30C makes it possible to adjust the level of the radio frequency current Iinc1.

The draw-off circuit 30 generates a draw-off current Is that is dependent on the level of the input current Iinc. More specifically, the draw-off circuit 30 generates a draw-off current Is that is dependent on the level of the radio frequency current Iinc1. A current corresponding to the draw-off current Is is drawn off from the bias current Ibp outputted from the peak-amplifier bias circuit 21, and the remaining current serves as an effective bias current for operating the peak amplifier 20.

The output signal of the peak amplifier 20 and the output signal of the carrier amplifier 10 are combined in a combiner 60. For example, the combiner 60 includes a 90° phase shifter 61. The 90° phase shifter 61 is, for example, a transmission line with a length of a quarter-wavelength. In the combiner 60, a signal outputted from the peak amplifier 20, and a signal outputted from the carrier amplifier 10 and passed through the 90° phase shifter 61 are combined. The resulting combined radio frequency signal is outputted as an output signal RFout via an impedance matching circuit 70. The output signal RFout is supplied to a load 71 with a load impedance ZL. The load 71 is, for example, a transmitting antenna.

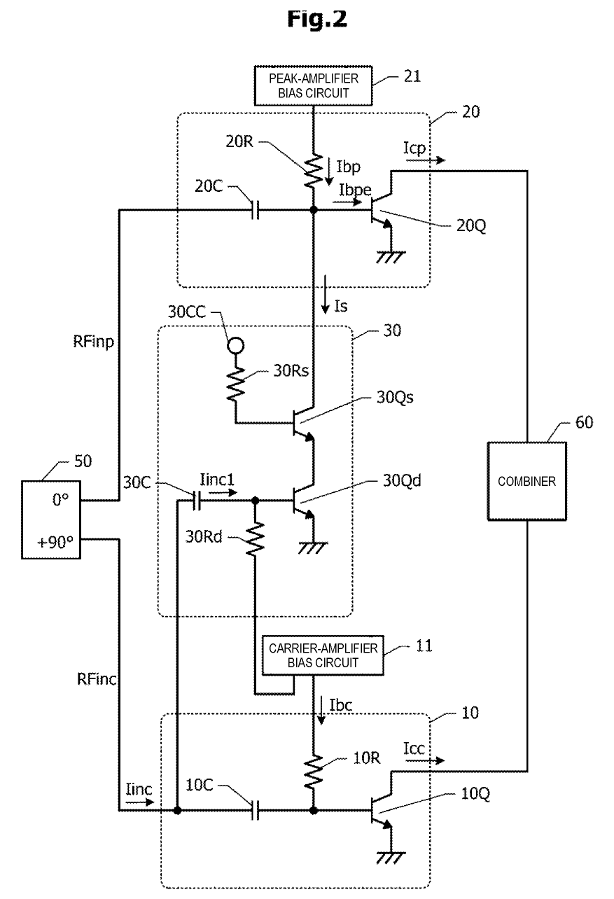

FIG. 2 is an equivalent circuit diagram of the carrier amplifier 10, the peak amplifier 20, and the draw-off circuit 30 of the Doherty amplifier according to the first embodiment.

The peak amplifier 20 includes a peak-amplifier transistor 20Q, a base ballast resistor 20R, and an input capacitor 20C. The peak-amplifier transistor 20Q is, for example, a heterojunction bipolar transistor.

The collector of the peak-amplifier transistor 20Q is connected to the combiner 60, and its emitter is grounded. The base of the peak-amplifier transistor 20Q is connected to the peak-amplifier bias circuit 21 via the base ballast resistor 20R and is also connected to the divider 50 via the input capacitor 20C. That is, the base ballast resistor 20R is inserted in a path through which a bias current is supplied from the peak-amplifier bias circuit 21 to the base of the peak-amplifier transistor 20Q. Further, the base of the peak-amplifier transistor 20Q is connected to the draw-off circuit 30.

The peak-amplifier input signal RFinp outputted from the divider 50 is inputted to the base of the peak-amplifier transistor 20Q via the input capacitor 20C. The bias current Ibp outputted from the peak-amplifier bias circuit 21 passes through the base ballast resistor 20R. Then, a portion (draw-off current Is) of the bias current Ibp flows into the draw-off circuit 30, and the remainder (effective bias current Ibpe) is supplied to the base of the peak-amplifier transistor 20Q.

The carrier amplifier 10 includes a carrier-amplifier transistor 10Q, a base ballast resistor 10R, and an input capacitor 10C. The carrier-amplifier transistor 10Q is, for example, a heterojunction bipolar transistor made of the same compound semiconductor material as that of the peak-amplifier transistor 20Q.

The collector of the carrier-amplifier transistor 10Q is connected to the combiner 60, and its emitter is grounded. The base of the carrier-amplifier transistor 10Q is connected to the carrier-amplifier bias circuit 11 via the base ballast resistor 10R and is also connected to the divider 50 via the input capacitor 10C.

The carrier-amplifier input signal RFinc outputted from the divider 50 is inputted to the base of the carrier-amplifier transistor 10Q via the input capacitor 10C. The bias current Ibc outputted from the carrier-amplifier bias circuit 11 is supplied to the base of the carrier-amplifier transistor 10Q via the base ballast resistor 10R.

The draw-off circuit 30 includes a common-base transistor 30Qs and a common-emitter transistor 30Qd that are cascode-connected. Each of the common-base transistor 30Qs and the common-emitter transistor 30Qd is, for example, a heterojunction bipolar transistor made of the same compound semiconductor material as that of the peak-amplifier transistor 20Q. A current that flows in a cascode circuit including the common-base transistor 30Qs and the common-emitter transistor 30Qd is the draw-off current Is.

The collector of the common-base transistor 30Qs is connected to the base of the peak-amplifier transistor 20Q. The base of the common-emitter transistor 30Qd is connected to the input node of the carrier amplifier 10 via the capacitor 30C. Further, the base of the common-emitter transistor 30Qd is connected to the carrier-amplifier bias circuit 11 via a resistor 30Rd.

A constant bias current is supplied from a constant current source 30CC to the common-base transistor 30Qs via a resistor 30Rs. The value of the constant bias current determines the maximum value of the collector current of the common-base transistor 30Qs. That is, the value of the constant bias current determines the maximum value of the draw-off current Is.

A bias current is supplied from the carrier-amplifier bias circuit 11 to the base of the common-emitter transistor 30Qd via the resistor 30Rd. The value of the bias current supplied to the base of the common-emitter transistor 30Qd is equal to the value of the bias current Ibc supplied to the base of the carrier-amplifier transistor 10Q. As with the carrier amplifier 10, the common-emitter transistor 30Qd is biased in class AB. Further, the radio frequency current Iinc1, which is a portion of the input current Iinc inputted to the carrier amplifier 10, is supplied to the base of the common-emitter transistor 30Qd via the capacitor 30C.

When the radio frequency current Iinc1 supplied to the base of the common-emitter transistor 30Qd increases, the collector current of the common-emitter transistor 30Qd increases due to the self-biasing effect.

The self-biasing effect will now be described briefly.

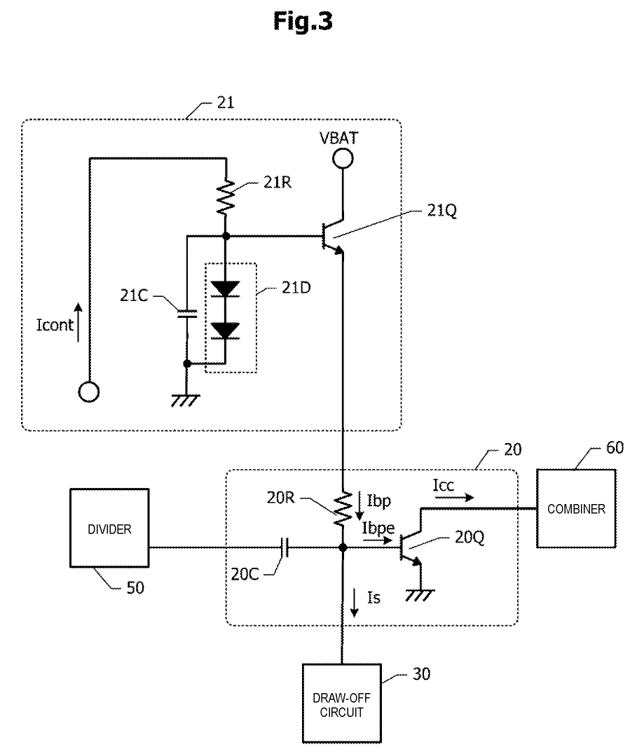

When the input signal level for a transistor increases, and the output signal level increases as a result, the amplitude of the collector current increases. As will be described later with reference to FIG. 3, the carrier-amplifier bias circuit 11 includes an emitter-follower transistor, and a bias current is supplied from the emitter of the emitter-follower transistor. When the amplitude of the input signal increases, the average bias point shifts higher as the emitter-follower transistor of the carrier-amplifier bias circuit 11 tends to maintain a constant potential difference between its base and its emitter. At this time, an increase in the positive direction of the amplitude is not restricted, and as a result, the direct-current component flowing through the collector and base of the common-emitter transistor 30Qd increases. This provides an effect substantially equivalent to an increase in base bias current. This effect is referred to as the self-biasing effect.

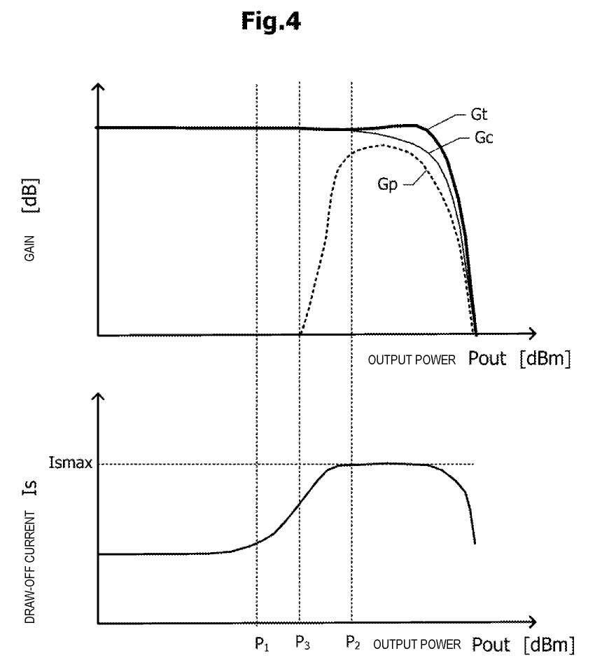

The increase in the collector current of the common-emitter transistor 30Qd due to the self-biasing effect is limited by the maximum value of the collector current of the common-base transistor 30Qs. That is, the draw-off current Is increases with increasing signal level of the carrier-amplifier input signal RFinc and becomes substantially constant upon reaching the maximum value of the collector current of the common-base transistor 30Qs. The manner in which the value of the draw-off current Is changes will be described in detail later with reference to FIG. 4.

FIG. 3 is an equivalent circuit diagram of the peak-amplifier bias circuit 21. The carrier-amplifier bias circuit 11 (FIGS. 1 and 2) is identical in circuit configuration to the peak-amplifier bias circuit 21, and thus a description of the configuration of the carrier-amplifier bias circuit 11 will be omitted below.

The peak-amplifier bias circuit 21 includes an emitter-follower transistor 21Q, a diode circuit 21D, a resistor 21R, and a capacitor 21C. The diode circuit 21D includes two diodes connected in series with each other. Each of the two diodes is implemented as, for example, a diode-connected heterojunction bipolar transistor.

One end of the resistor 21R is connected to the anode-side node of the diode circuit 21D. The cathode-side node of the diode circuit 21D is grounded. The capacitor 21C is connected in parallel to the diode circuit 21D. A constant current Icont is supplied to the resistor 21R at the other end of the resistor 21R. A constant voltage based on the forward voltage of the diode is generated at the interconnection point between the resistor 21R and the diode circuit 21D. The interconnection point between the resistor 21R and the diode circuit 21D is connected to the base of the emitter-follower transistor 21Q.

A constant voltage VBAT is applied to the collector of the emitter-follower transistor 21Q. The emitter of the emitter-follower transistor 21Q is connected to the base of the peak-amplifier transistor 20Q via the base ballast resistor 20R. A substantially constant bias current Ibp is supplied from the emitter-follower transistor 21Q to the base ballast resistor 20R of the peak amplifier 20.

A current corresponding to the draw-off current Is generated in the draw-off circuit 30 is drawn off from the bias current Ibp, and the effective bias current Ibpe, which is the remaining current, is supplied to the base of the peak-amplifier transistor 20Q.

The operation of the Doherty amplifier according to the first embodiment will now be described with reference to FIG. 4.

FIG. 4 illustrates graphs representing the relationship between output power Pout and each of gain and draw-off current. The top graph represents the relationship between the output power Pout of the Doherty amplifier and gain, and the bottom graph represents the relationship between the output power Pout of the Doherty amplifier and the draw-off current Is. The horizontal axis in each of the top and bottom graphs in FIG. 4 represents the output power Pout, the vertical axis in the top graph represents gain, and the vertical axis in the bottom graph represents the value of the draw-off current Is. The dashed line in the top graph represents a gain Gp of the peak amplifier 20 (FIG. 1), the thin solid line represents a gain Gc of the carrier amplifier 10 (FIG. 1), and the thick solid line represents a gain Gt of the Doherty amplifier, that is, the sum of the gain of the peak amplifier 20 and the gain of the carrier amplifier 10.

When the output power Pout is less than or equal to a power level P₁, the carrier-amplifier input signal RFinc is also at a low power level, and the common-emitter transistor 30Qd (FIG. 2) of the draw-off circuit 30 conducts the draw-off current Is corresponding to a constant bias current supplied from the carrier-amplifier bias circuit 11 (FIG. 2).

When the output power Pout exceeds the power level P₁, the common-emitter transistor 30Qd becomes self-biased, and thus the draw-off current Is increases with increasing output power Pout. When the draw-off current Is reaches a maximum value Ismax of the collector current of the common-base transistor 30Qs, the draw-off current Is becomes substantially constant. With the draw-off current Is now being substantially constant, the gain Gp of the peak amplifier 20 reaches a target value.

The gain Gc of the carrier amplifier 10 (FIG. 2) is substantially constant when the output power Pout is lower than or equal to the power level P₂, and once the output power Pout exceeds the power level P₂, the gain Gc decreases as the output power Pout increases. The power level P₂ can be regarded as, for example, the output power Pout at which the gain Gc indicates the 1-dB gain compression level (P1dB).

When the output power Pout increases, the bias current of the peak-amplifier transistor 20Q (FIG. 2) increases due to the self-biasing effect. As a result, the gain Gp of the peak amplifier 20 rises. However, as the output power Pout increases, the draw-off current Is also increases, which limits an increase in the effective bias current Ibpe of the peak-amplifier transistor 20Q. In this way, the increase in the power level of the carrier-amplifier input signal RFinc inhibits the rise of the gain of the peak amplifier 20. Consequently, a power level P₃ of the output power Pout at which the gain Gp of the peak amplifier 20 rises shifts higher, as compared with the configuration without the draw-off current Is.

Effects according to the first embodiment will now be described through comparison with a comparative example.

For instance, according to the comparative example, when the output power Pout is greater than or equal to the power level P₃, the bias current is increased as compared with when the output power Pout is less than the power level P₃. Increasing the bias current of the peak amplifier causes the gain of the peak amplifier to increase, which compensates for a decrease in the gain of the carrier amplifier. This allows the overall gain of the Doherty amplifier to remain constant.

However, in amplifying high-PAPR radio frequency signals, even when, for example, the output power Pout is in a range from the power level P₁ to the power level P₃(FIG. 4), the bias current of the peak amplifier may be increased in advance in anticipation of the possibility that the output power Pout may become greater than or equal to the power level P₃. Thus, the peak amplifier has some gain when the output power Pout is in the range from the power level P₁ to the power level P₃. This results in degradation of PAE when the output power Pout is in the range from the power level P₁ to the power level P₃.

According to the first embodiment, the gain Gp of the peak amplifier 20 (FIG. 2) is nearly zero when the output power Pout is in the range from the power level P₁ to the power level P₃. Once the output power Pout exceeds the power level P₃, the gain Gp of the peak amplifier 20 rises automatically. This makes it possible, even in the case of high-PAPR radio frequency signals, to sufficiently follow changes in the output power Pout and keep the gain Gt (FIG. 4) of the Doherty amplifier substantially constant. The peak amplifier 20 (FIG. 1) thus stays nearly inactive when the output power Pout is in the range from the power level P₁ to the power level P₃. This mitigates PAE degradation.

According to the first embodiment, by adjusting, for example, the capacitance of the capacitor 30C (FIG. 2) or the emitter dimensions of the common-emitter transistor 30Qd to thus adjust the amplitude of the radio frequency current inputted to the base of the common-emitter transistor 30Qd, the gain profile of the peak amplifier 20 can be adjusted. This allows the total gain of the Doherty amplifier to be made flatter.

A Doherty amplifier according to a modification of the first embodiment will now be described.

According to the first embodiment, the combiner 60 (FIG. 1) is a current combiner. Alternatively, however, the combiner 60 may be a voltage combiner. According to the first embodiment, a portion of the input current Iinc for the carrier amplifier 10 is inputted to the draw-off circuit 30. Alternatively, however, a portion of the input current Iinp for the peak amplifier, instead of the input current Iinc, may be inputted to the draw-off circuit 30.

According to the first embodiment, the common-emitter transistor 30Qd of the draw-off circuit 30 and the carrier-amplifier transistor 10Q share the carrier-amplifier bias circuit 11 (FIG. 2). According to the modification, a bias current may be supplied to the common-emitter transistor 30Qd of the draw-off circuit 30 from a bias circuit different from the carrier-amplifier bias circuit 11. This configuration allows for increased flexibility in setting the bias current of the common-emitter transistor 30Qd of the draw-off circuit 30.

According to the first embodiment, a constant bias current is supplied from the constant current source 30CC to the base of the common-base transistor 30Qs of the draw-off circuit 30. Stopping the supply of the bias current causes the draw-off current Is to become zero. As a result, the effective bias current Ibpe of the peak-amplifier transistor 20Q becomes equal to the bias current Ibp outputted from the peak-amplifier bias circuit 21. This allows the peak amplifier 20 to operate with a fixed bias.

### (Second Embodiment)

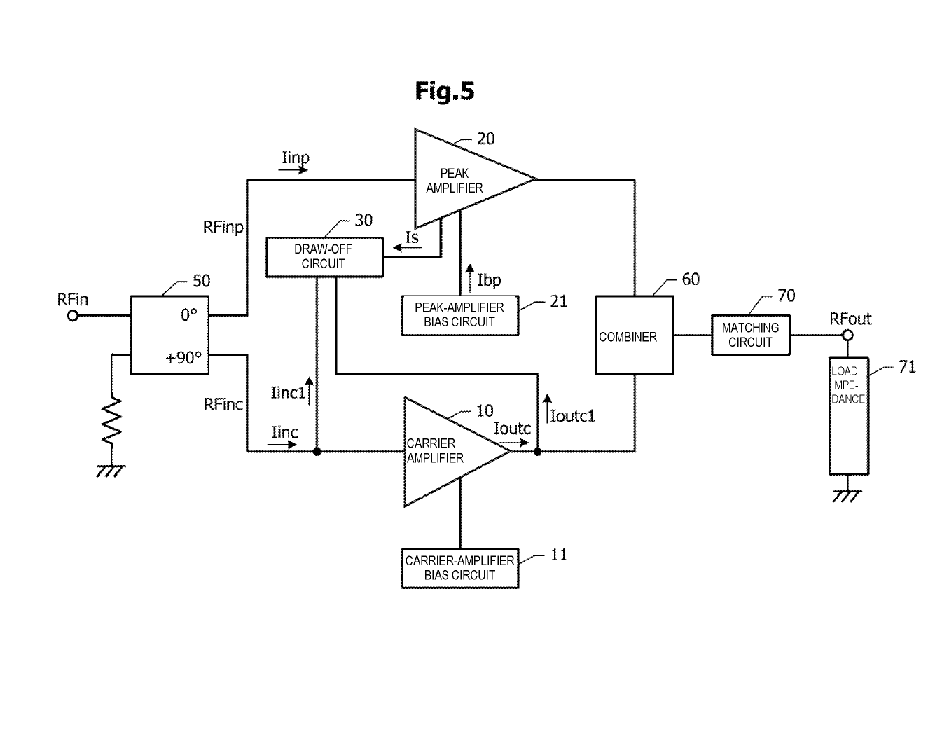

A Doherty amplifier according to a second embodiment will now be described with reference to FIGS. 5 to 9. Features similar to those of the Doherty amplifier according to the first embodiment described above with reference to FIGS. 1 to 4 will not be described below in further detail.

FIG. 5 is a block diagram of the Doherty amplifier according to the second embodiment. According to the first embodiment, the radio frequency current Iinc1, which is a portion of the input current Iinc for the carrier amplifier 10, is inputted to the draw-off circuit 30. In contrast, according to the second embodiment, in addition to the radio frequency current Iinc1, a radio frequency current Ioutc1, which is a portion of an output current Ioutc outputted from the carrier amplifier 10, is also inputted to the draw-off circuit 30. The level of the radio frequency current Ioutc1 is determined in accordance with the level of the output current Iout, the input impedance of the combiner 60 seen from the output port of the carrier amplifier 10, and the input impedance of the draw-off circuit 30 seen from the output port of the carrier amplifier 10.

As with the first embodiment, the draw-off circuit 30 increases the draw-off current Is as the input current Iinc for the carrier amplifier 10 increases. According to the second embodiment, the draw-off circuit 30 further adjusts the draw-off current Is in accordance with the level of the output current Ioutc outputted from the carrier amplifier 10. Specifically, the draw-off circuit 30 reduces the degree of increase in the draw-off current Is as the level of the output current Ioutc, for example, the amplitude of the output current Ioutc increases.

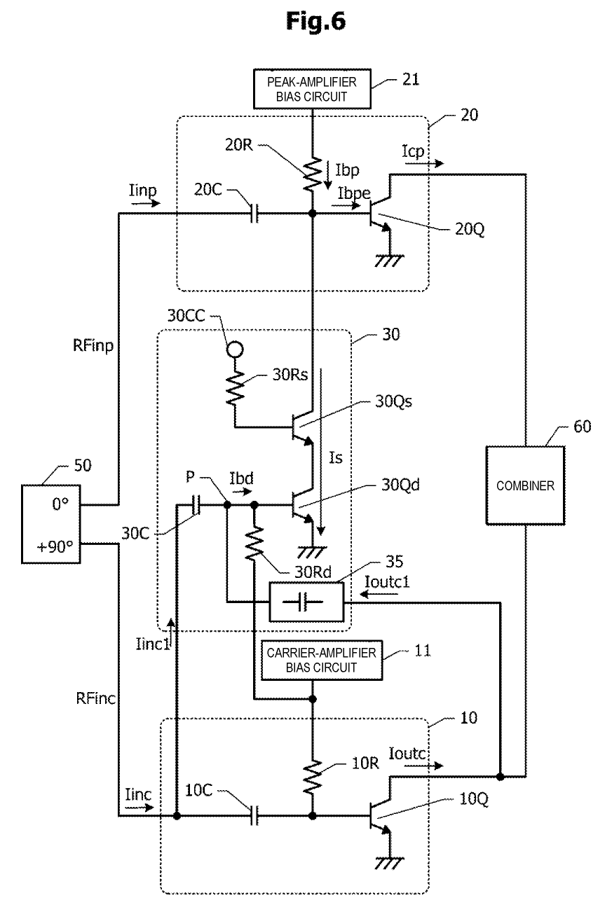

FIG. 6 is an equivalent circuit diagram of the carrier amplifier 10, the peak amplifier 20, and the draw-off circuit 30 of the Doherty amplifier according to the second embodiment. The base of the common-emitter transistor 30Qd of the draw-off circuit 30 is connected to the output port of the carrier amplifier 10 via an attenuator 35. The attenuator 35 supplies the radio frequency current Ioutc1, which is reduced in level relative to the output current Ioutc outputted from the carrier amplifier 10, to the base of the common-emitter transistor 30Qd. As the attenuator 35, for example, a capacitor is used. Alternatively, a plurality of other passive elements may constitute the attenuator 35. For example, the attenuator 35 may be implemented by a circuit including a capacitor and a resistor that are connected in series.

The level (e.g., amplitude) of the radio frequency current Ioutc1 is determined in accordance with the input impedance of the combiner 60 seen from the carrier amplifier 10, and the input impedance of the draw-off circuit 30 seen from the carrier amplifier 10. Varying the impedance of the attenuator 35 makes it possible to adjust the level of the radio frequency current Ioutc1.

The radio frequency current Iinc1 supplied from the input port of the carrier amplifier 10, and the radio frequency current Ioutc1 supplied from the output port of the carrier amplifier 10 are combined to produce a radio frequency current Ibd, which is supplied to the base of the common-emitter transistor 30Qd.

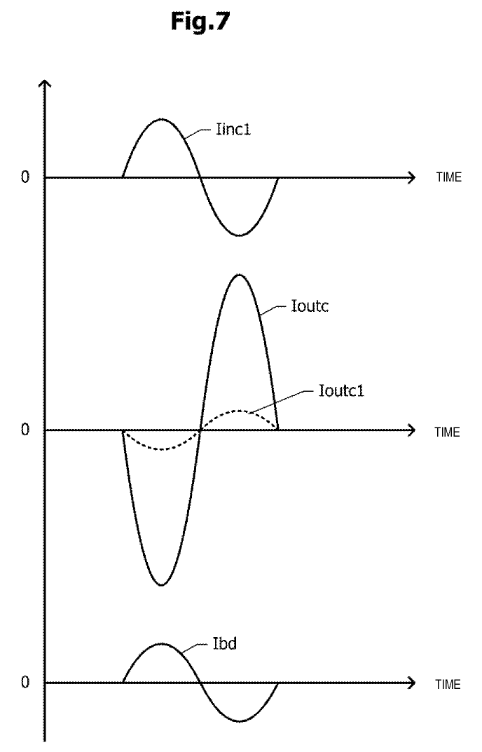

FIG. 7 illustrates graphs representing an example of the respective waveforms over one period of the radio frequency current Ibd, the radio frequency current Iinc1, and the radio frequency current Ioutc1, which are supplied to the base of the common-emitter transistor 30Qd. The output current Ioutc outputted from the carrier amplifier 10 is inverted in phase relative to the input current Iinc inputted to the carrier amplifier. Further, at the junction P between the current path from the input node of the carrier amplifier 10 to the base of the common-emitter transistor 30Qd and the current path from the output node of the carrier amplifier 10 to the base of the common-emitter transistor 30Qd, the radio frequency current Iinc1 and the radio frequency current Ioutc1 are inverted in phase relative to each other.

The respective circuit constants of the capacitor 30C (FIG. 6) and the attenuator 35 (FIG. 6) are set such that the radio frequency current Ioutc1 is smaller in amplitude than the radio frequency current Iinc1. The radio frequency current Ibd is in phase with the radio frequency current Iinc1, and its amplitude is less than the amplitude of the radio frequency current Iinc1. That is, when the first embodiment (FIG. 2) and the second embodiment (FIG. 6) are compared under the same operating conditions, the amplitude of the radio frequency current Ibd supplied to the base of the common-emitter transistor 30Qd is smaller in the second embodiment than in the first embodiment. When the amplitude of the radio frequency current Ibd decreases, the self-biasing effect on the common-emitter transistor 30Qd decreases, and the draw-off current Is thus decreases.

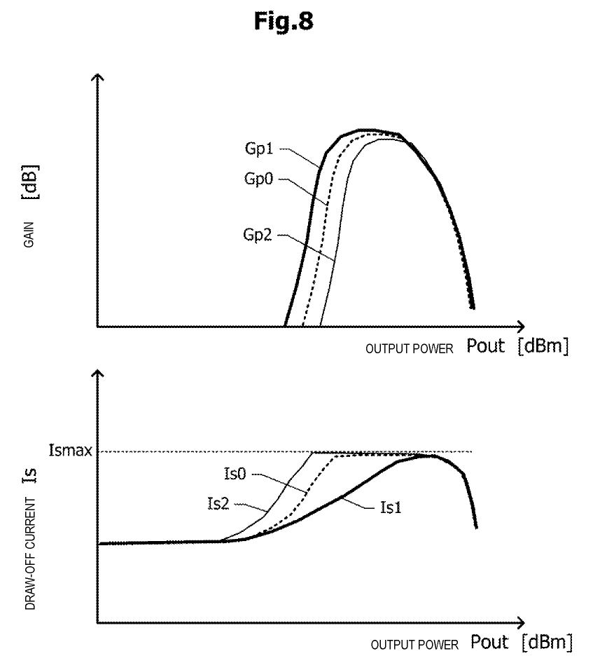

FIG. 8 illustrates graphs representing the relationship between the output power Pout and each of gain and draw-off current. The top graph of FIG. 8 represents the relationship between the output power Pout of the Doherty amplifier and the gain of the peak amplifier 20, and the bottom graph represents the relationship between the output power Pout of the Doherty amplifier and the draw-off current Is.

It is now assumed that when the load impedance ZL (FIG. 1) is at its design value, and the voltage standing wave ratio (VSWR) is 1, a draw-off current Is0 is obtained with respect to the output power Pout. According to the second embodiment, the radio frequency current Ibd (FIG. 6) supplied to the base of the common-emitter transistor 30Qd has a small amplitude as compared with the first embodiment (FIG. 4). Consequently, when the output power Pout increases, the draw-off current Is0 increases less than does the draw-off current Is illustrated in FIG. 4.

When the load impedance ZL (FIG. 1) becomes higher than its design value, the amplitude of the output current Ioutc outputted from the carrier amplifier 10 increases. When the amplitude of the output current Ioutc increases, so does the amplitude that the radio frequency current Ioutc1 (FIG. 6) has after passing through the attenuator 35. As previously described with reference to FIG. 7, such an increase in the amplitude of the radio frequency current Ioutc1 causes a decrease in the amplitude of the radio frequency current Ibd supplied to the base of the common-emitter transistor 30Qd.

This reduces the self-biasing effect that appears in the common-emitter transistor 30Qd. As a result, a draw-off current Is1 in this case becomes smaller than the draw-off current Is0 when VSWR is 1. Until the draw-off current Is0 reaches the maximum value Ismax, the decrease in the draw-off current Is1 relative to the draw-off current Is0 increases as the output power Pout increases.

As the draw-off current Is1 becomes lower than the draw-off current Is0, its effect on reducing the effective bias current Ibpe (FIG. 5) decreases. As a result, the power level of the output power Pout at which the gain Gp1 of the peak amplifier 20 rises shifts lower relative to the power level at which the gain Gp0 of the peak amplifier 20 rises when VSWR is 1. Further, as compared with the gain Gp0, the gain Gp1 reaches a sufficiently high level even at a lower level of the output power Pout.

When the load impedance ZL (FIG. 1) becomes lower than its design value, the amplitude of the output current Ioutc from the carrier amplifier 10 decreases. Accordingly, contrary to the case of the draw-off current Is1 when the load impedance ZL (FIG. 1) becomes higher than its design value, a draw-off current Is2 in this case increases relative to the draw-off current Is0 when VSWR is 1.

As the draw-off current Is2 increases, its effect on reducing the effective bias current Ibpe (FIG. 5) increases. As a result, the power level of the output power Pout at which the gain Gp2 of the peak amplifier 20 rises shifts higher relative to the power level at which the gain Gp0 of the peak amplifier 20 rises when VSWR is 1.

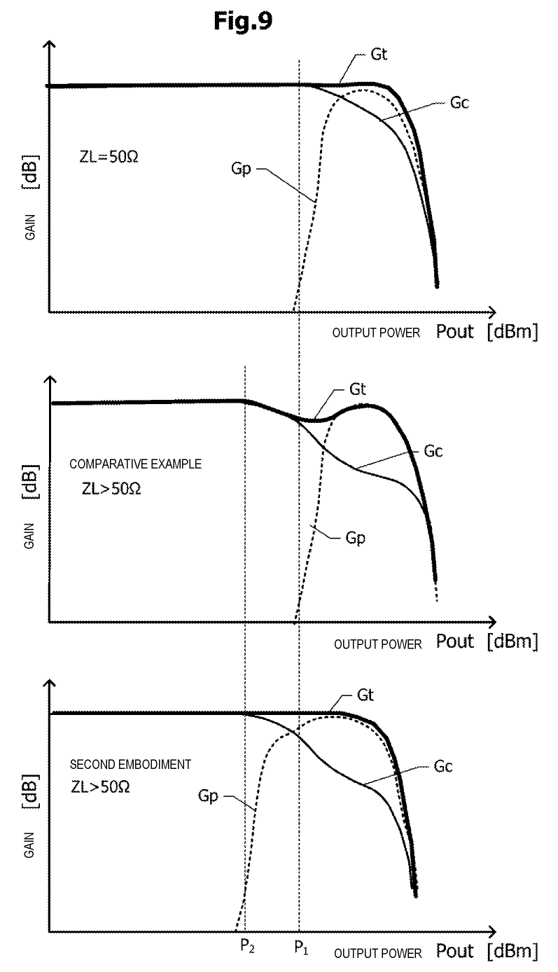

Effects according to the second embodiment will now be described with reference to FIG. 9.

FIG. 9 illustrates graphs representing the relationship between gain and the output power Pout. The top graph of FIG. 9 represents the gain when the load impedance ZL is at its design value (e.g., 50 Ω), that is, when the Doherty amplifier and the load impedance ZL are impedance-matched to each other, and VSWR is 1, the middle graph represents the gain of the Doherty amplifier according to the comparative example when the load impedance ZL is higher than 50 Ω, and the bottom graph represents the gain of the Doherty amplifier according to the second embodiment when the load impedance ZL is higher than 50 Ω. The horizontal axis in each of these graphs represents the output power Pout of the Doherty amplifier, and the vertical axis represents gain. The dashed line in each graph represents the gain Gp of the peak amplifier, the thin solid line represents the gain Gc of the carrier amplifier, and the thick solid line represents the total gain Gt of the Doherty amplifier.

As illustrated in the top graph, when impedance is matched, the gain Gp of the peak amplifier rises at the power level P₁ so as to compensate for a decrease in the gain Gc of the carrier amplifier associated with an increase in the output power Pout. This makes it possible to ensure sufficient flatness of the gain Gt of the Doherty amplifier.

When the load impedance ZL becomes higher than 50 Ω, impedance is no longer matched, and the gain Gc of the carrier amplifier thus starts to decrease at the power level P₂ of the output power Pout, which is lower than the power level P₁ at which the gain Gc starts to decrease when impedance is matched. Further, the gain Gc of the carrier amplifier in this case decreases more with increasing output power Pout than when impedance is matched.

In the comparative example in the middle graph of FIG. 9, even when the load impedance ZL is higher than 50 Ω, the gain Gp of the peak amplifier rises at the power level P₁as in the case of the top graph. Consequently, when the output power Pout is greater than or equal to the power level P₂, the gain Gt of the Doherty amplifier decreases significantly relative to when impedance is matched. In other words, the input/output characteristics no longer remain linear with respect to an increase in the output power Pout.

According to the second embodiment, when the load impedance ZL is higher than 50 Ω, as described above with reference to FIG. 8, the gain Gp1 of the peak amplifier 20 (FIG. 6) in this case rises earlier than does the gain Gp0 when impedance is matched, and the gain Gp1 reaches a sufficiently high level even when the output power Pout is relatively low. For example, the gain Gp of the peak amplifier 20 rises from the vicinity of the power level P₂. This makes it possible to compensate for the drop in the gain Gc of the carrier amplifier 10, even when the output power Pout at which the gain Gc of the carrier amplifier 10 (FIG. 6) starts to drop decreases to the power level P₂. The above-mentioned operation makes it possible to ensure sufficient flatness of the gain Gt of the Doherty amplifier.

As described above, according to the second embodiment, when VSWR changes due to variation of the load impedance ZL (FIG. 1), the power level at which the gain of the peak amplifier 20 (FIGS. 5 and 6) rises shifts in response to the change in VSWR. As a result, a drop in the gain of the carrier amplifier 10 (FIGS. 5 and 6) due to variation of the load impedance ZL is properly compensated for by the peak amplifier 20. This makes it possible to ensure sufficient flatness of the gain Gt of the Doherty amplifier.

### (Third Embodiment)

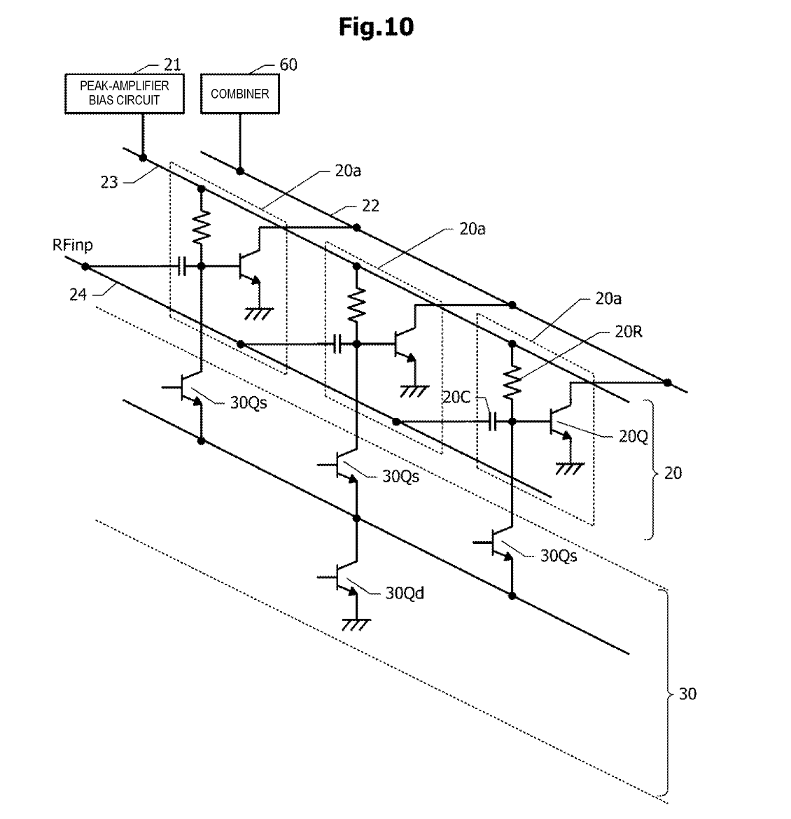

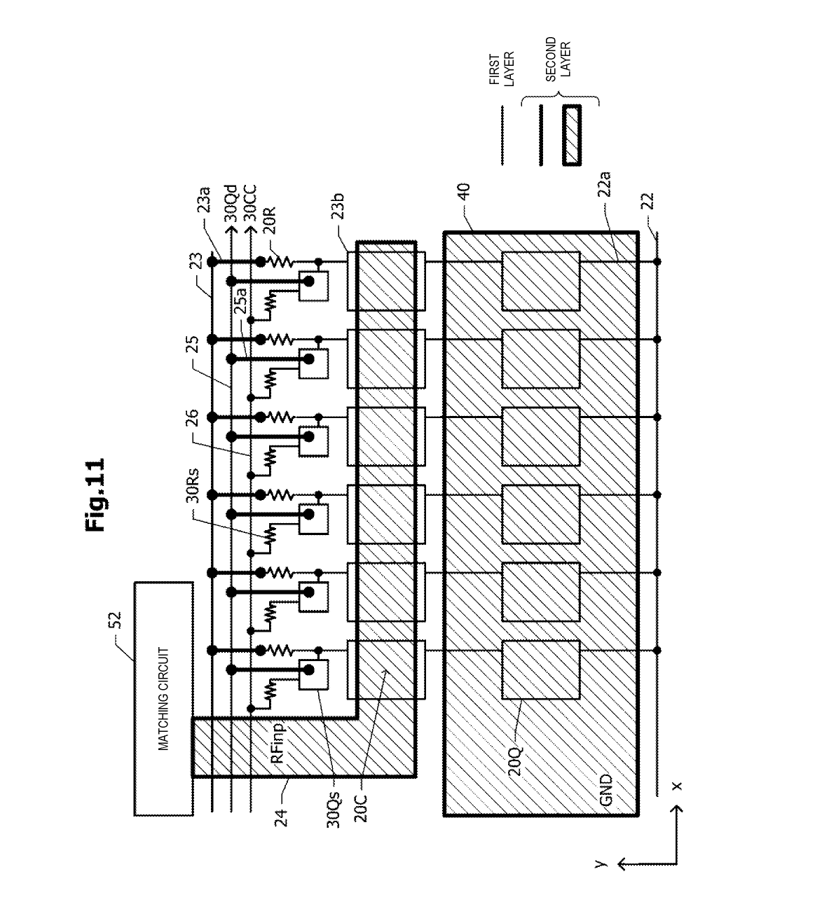

A Doherty amplifier according to a third embodiment will now be described with reference to FIGS. 10 and 11. Features similar to those of the Doherty amplifier according to the second embodiment described above with reference to FIGS. 5 to 9 will not be described below in further detail.

FIG. 10 is an equivalent circuit diagram of the peak amplifier 20 and the draw-off circuit 30 of the Doherty amplifier according to the third embodiment. In the Doherty amplifier according to the third embodiment, the peak amplifier 20 includes a plurality of cells 20a connected in parallel to each other. As with the peak amplifier 20 (FIG. 2) of the Doherty amplifier according to the first embodiment, each of the cells 20a includes the peak-amplifier transistor 20Q, the base ballast resistor 20R, and the input capacitor 20C.

The collector of the peak-amplifier transistor 20Q of each of the cells 20a is connected to the combiner 60 via a common collector wiring line 22. One end of the base ballast resistor 20R of each of the cells 20a is connected to the peak-amplifier bias circuit 21 via a common bias wiring line 23. One electrode of the input capacitor 20C of each of the cells 20a is connected to a common input wiring line 24. The peak-amplifier input signal RFinp is inputted from the common input wiring line 24 to the base of the peak-amplifier transistor 20Q via the input capacitor 20C of the corresponding one of the cells 20a.

The draw-off circuit 30 includes a plurality of common-base transistors 30Qs each provided for the corresponding cell 20a. The collector of each of the common-base transistors 30Qs is connected to the base of the peak-amplifier transistor 20Q of the corresponding cell 20a. The emitters of the common-base transistors 30Qs are tied together and connected to the collector of a single common-emitter transistor 30Qd.

FIG. 11 is a diagram illustrating the layout of elements constituting part of the peak amplifier and draw-off circuit of the Doherty amplifier according to the third embodiment. In FIG. 11, the thin solid lines represent conductor patterns disposed in the first wiring layer, and the thick solid lines and hatched patterns bounded by the thick solid lines represent conductor patterns disposed in the second wiring layer.

A plurality of peak-amplifier transistors 20Q are arranged in a row on the surface of a semiconductor substrate, for example, a GaAs substrate. An x-y rectangular coordinate system is defined on the surface of the semiconductor substrate, with the x-axis direction being the direction of arrangement of the peak-amplifier transistors 20Q. A plurality of input capacitors 20C and a plurality of common-base transistors 30Qs are also arranged in a row in the x-direction. Further, a second common wiring line 26, a first common wiring line 25, the bias wiring line 23, and the collector wiring line 22 are disposed so as to extend in the x-direction.

The collector wiring line 22, the row of peak-amplifier transistors 20Q, the row of input capacitors 20C, the row of common-base transistors 30Qs, the second common wiring line 26, the first common wiring line 25, and the bias wiring line 23 are disposed in the stated order in the positive direction of the y-axis.

Each of the input capacitors 20C is provided in the region where an input-capacitor lower wiring line 23b disposed in the first layer and the input wiring line 24 disposed in the second layer overlap. A plurality of input-capacitor lower wiring lines 23b are each connected to the base of the peak-amplifier transistor 20Q via the wiring disposed in the first layer. The input wiring line 24 extends in the x-direction and is shared by the input capacitors 20C.

The input-capacitor lower wiring lines 23b are each connected to the common bias wiring line 23 via the base ballast resistor 20R and an individual bias wiring line 23a. The base ballast resistor 20R is disposed in the first wiring layer between the second common wiring line 26 and the corresponding one of the row of input capacitors 20C, and the individual bias wiring line 23a is disposed in the second wiring layer. The individual bias wiring line 23a crosses the first common wiring line 25 and the second common wiring line 26, which are disposed in the first layer.

The collector of each of the common-base transistors 30Qs is connected to the input-capacitor lower wiring line 23b via the wiring disposed in the first layer. The base of each of the common-base transistors 30Qs is connected to the second common wiring line 26 via the resistor 30Rs. The resistor 30Rs is disposed in the first layer between the second common wiring line 26 and the corresponding one of the row of common-base transistors 30Qs. The second common wiring line 26 is connected to the constant current source 30CC (FIG. 2).

The emitter of each of the common-base transistors 30Qs is connected to the first common wiring line 25 via a first individual wiring line 25a. The first individual wiring line 25a is disposed in the second wiring layer and crosses the second common wiring line 26 disposed in the first layer. The first common wiring line 25 is connected to the collector of the common-emitter transistor 30Qd (FIG. 10).

A matching circuit 52 is disposed on the positive side of the y-axis relative to the bias wiring line 23. The input wiring line 24 in the second layer is connected to the matching circuit 52 at a position where the input wiring line 24 does not overlap the row of common-base transistors 30Qs with respect to the x-direction. The input wiring line 24 in the second layer crosses the second common wiring line 26, the first common wiring line 25, and the bias wiring line 23, which are disposed in the first layer. The peak-amplifier input signal RFinp is inputted to each of the input capacitors 20C via the matching circuit 52 and the input wiring line 24. In FIG. 2, no matching circuit is inserted between the peak amplifier 20 and the divider 50. In the case of such a configuration with no matching circuit inserted, the divider 50 is disposed at the position where the matching circuit 52 is located in FIG. 11. Alternatively, in FIG. 2, a matching circuit may be inserted between the peak amplifier 20 and the divider 50.

The collector of each of the peak-amplifier transistors 20Q is connected to the common collector wiring line 22 via an individual collector wiring line 22a. A plurality of individual collector wiring lines 22a and the common collector wiring line 22 are disposed in the first wiring layer.

A ground pad 40 extending in the x-direction is disposed so as to overlap the row of peak-amplifier transistors 20Q. The ground pad 40 is disposed in the second wiring layer and connected to the respective emitters of the peak-amplifier transistors 20Q. A ground bump (not illustrated) is disposed so as to overlap the ground pad 40. The ground bump serves to provide a ground potential GND to the ground pad 40 and also serves as a path of heat dissipation from the peak-amplifier transistor 20Q. To ensure the stability of the ground potential GND and sufficient heat dissipation characteristics, each of the ground bump and the ground pad 40 may have a dimension in the y-direction greater than the dimension in the y-direction of the peak-amplifier transistor 20Q.

The reason for providing the common-base transistor 30Qs of the draw-off circuit 30 for each of the cells 20a will now be described. If there are temperature variations among the cells 20a, current concentrates in the cell 20a that is at a high temperature relative to the other cells 20a, and the cell 20a at the high temperature further rises in temperature. Such current concentration in a particular cell 20a may lead to thermal runaway. When the bias current of the particular cell 20a increases, a voltage drop due to the base ballast resistor 20R increases. The increase in voltage drop causes the collector current to decrease, which mitigates thermal runaway. Accordingly, such a voltage drop due to the base ballast resistor 20R needs to occur independently for each of the cells 20a.

In the case of a configuration in which only a single common-base transistor 30Qs of the draw-off circuit 30 is provided for the cells 20a, the base ballast resistor 20R of each of the cells 20a is connected at one end to the collector of the single common-base transistor 30Qs. With this configuration, the base ballast resistors 20R are connected in parallel to each other, and thus the cells 20a experience the same voltage drop due to the base ballast resistor 20R. This makes it impossible to mitigate thermal runaway caused by concentration of current in a particular cell 20a.

When the common-base transistor 30Qs is provided for each cell 20a, the voltage drop due to the base ballast resistor 20R occurs independently for each cell 20a. This effectively allows the thermal runaway mitigation effect to be maintained.

As with the peak amplifier 20, the carrier amplifier 10 (FIG. 1) also includes a plurality of cells connected in parallel to each other.

Effects of the third embodiment will now be described.

According to the third embodiment, the peak amplifier 20 includes a plurality of cells 20a, and the carrier amplifier 10 (FIG. 1) also includes a plurality of cells. This configuration allows for increased output power.

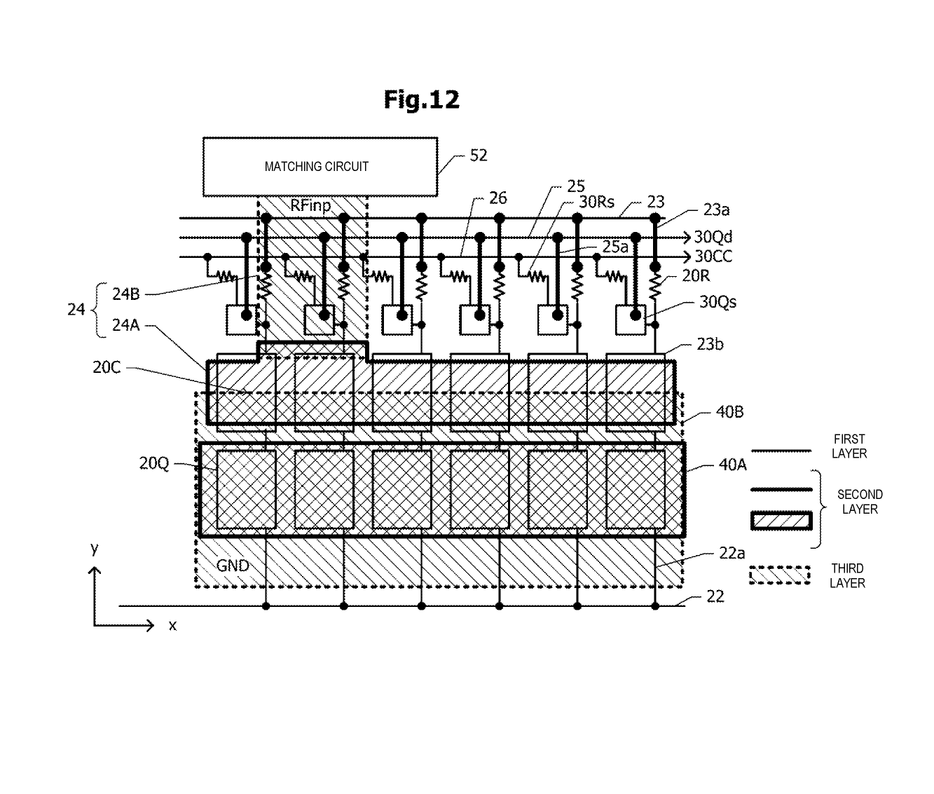

A Doherty amplifier according to a modification of the third embodiment will now be described with reference to FIG. 12. FIG. 12 is a diagram illustrating the layout of elements constituting part of the peak amplifier and draw-off circuit of the Doherty amplifier according to the modification of the third embodiment.

The Doherty amplifier according to the third embodiment (FIG. 11) includes two wiring layers. In contrast, the Doherty amplifier according to the modification of the third embodiment illustrated in FIG. 12 includes three wiring layers. In FIG. 12, the thin solid lines represent conductor patterns disposed in the first wiring layer, the thick solid lines and the patterns bounded by the thick solid lines and indicated with hatching that slants upwards to the right represent conductor patterns disposed in the second wiring layer, and the patterns indicated with hatching that slants downward to the right and bounded by the thick dashed lines represent conductor patterns disposed in the third wiring layer.

According to the third embodiment (FIG. 11) illustrated in FIG. 11, the input wiring line 24 is disposed in the second wiring layer. In contrast, according to the modification of the third embodiment illustrated in FIG. 12, the input wiring line 24 includes a second-layer input wiring line 24A disposed in the second wiring layer, and a third-layer input wiring line 24B disposed in the third wiring layer. The second-layer input wiring line 24A overlaps each of the input-capacitor lower wiring lines 23b, and the input capacitor 20C is provided in the overlapping area. The third-layer input wiring line 24B extends in the positive direction of the y-axis from an area overlapping the second-layer input wiring line 24A, crosses the row of base-grounded transistors 30Qs, the second common wiring line 26, the first common wiring line 25, and the bias wiring line 23, and reaches the matching circuit 52. The second-layer input wiring line 24A and the third-layer input wiring line 24B are connected to each other in a region where the two input wiring lines overlap.

According to the third embodiment (FIG. 11), the ground pad 40 is disposed in the second wiring layer. In contrast, according to the modification of the third embodiment illustrated in FIG. 12, a ground pad 40B is disposed in the third wiring layer. The ground pad 40B disposed in the third layer is connected to the emitter of each of the peak-amplifier transistors 20Q via a conductor pattern 40A disposed in the second wiring layer. The conductor pattern 40A disposed in the second layer has a dimension in the y-direction less than the dimension in the y-direction of the ground pad 40B disposed in the third layer.

A portion located at the negative side of the y-axis of the second-layer input wiring line 24A overlaps a portion located at the positive side of the y-axis of the ground pad 40B disposed in the third layer. A portion located at the negative side of the y-axis of the input-capacitor lower wiring line 23b also overlaps a portion located at the positive side of the y-axis of the ground pad 40B. That is, a portion of the input capacitor 20C overlaps a portion of the ground pad 40B. Thus, according to the modification of the third embodiment illustrated in FIG. 12, the spacing in the y-direction between the peak-amplifier transistor 20Q and the input capacitor 20C is narrow as compared with the third embodiment illustrated in FIG. 11.

According to the modification of the third embodiment illustrated in FIG. 12, the wiring layer includes three layers, which is disadvantageous in terms of cost as compared with the third embodiment (FIG. 11) in which the wiring layer includes two layers. However, since the input wiring line 24B can be routed to cross the row of common-base transistors 30Qs, the input wiring line 24 can be reduced in dimension in the x-direction as compared with the third embodiment. Further, as compared with the third embodiment, the spacing in the y-direction between the input capacitor 20C and the peak-amplifier transistor 20Q can be reduced. This makes it possible to reduce the dimension of the Doherty amplifier in the y-direction.

Further, the third-layer input wiring line 24B, which connects the second-layer input wiring line 24A and the matching circuit 52, is located at a position where the third-layer input wiring line 24B crosses the common-base transistor 30Qs, the bias wiring line 23, the first common wiring line 25, and the second common wiring line 26. This makes it possible to reduce the dimension of the Doherty amplifier in the x-direction.

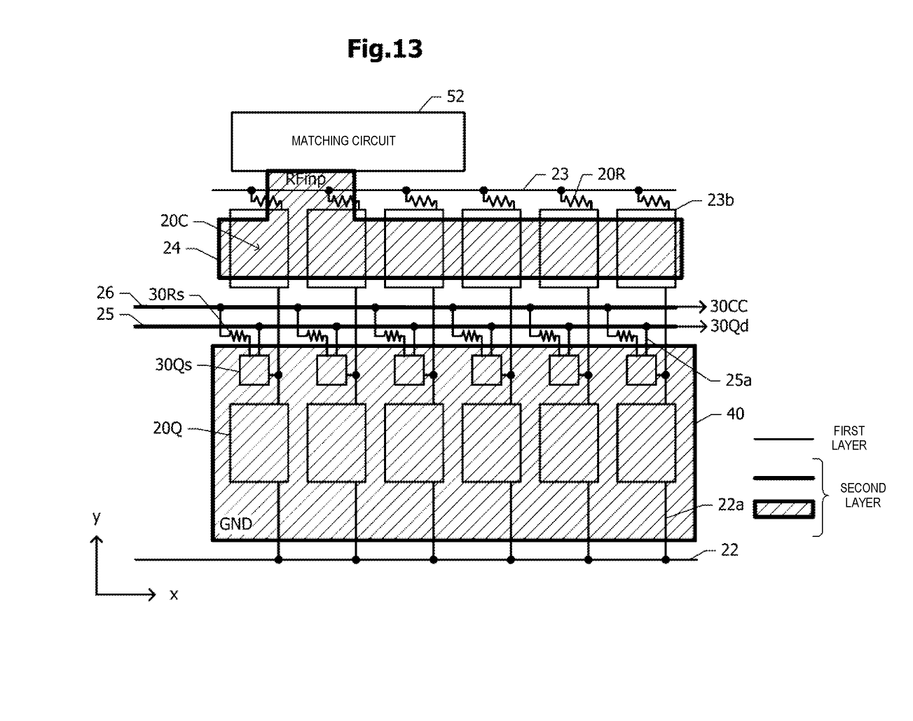

A Doherty amplifier according to another modification of the third embodiment will now be described with reference to FIG. 13. FIG. 13 is a diagram illustrating the layout of elements constituting part of the peak amplifier and draw-off circuit of the Doherty amplifier according to the other modification of the third embodiment.

According to the modification illustrated in FIG. 13, a row of common-base transistors 30Qs, the first common wiring line 25, and the second common wiring line 26 are disposed between a row of peak-amplifier transistors 20Q and a row of input capacitors 20C with respect to the y-direction. Since the first common wiring line 25 and the second common wiring line 26 cross the wiring in the first layer that connects the input-capacitor lower wiring line 23b to the base of the peak-amplifier transistor 20Q, the first common wiring line 25 and the second common wiring line 26 are disposed in the second wiring layer.

As with the configuration according to the third embodiment (FIG. 11), the bias wiring line 23 is disposed between the row of input capacitors 20C and the matching circuit 52. The base ballast resistor 20R is disposed between the corresponding one of the row of input capacitors 20C and the bias wiring line 23. The bias wiring line 23 and the base ballast resistor 20R, which are disposed between the corresponding one of the row of input capacitors 20C and the matching circuit 52, are both disposed in the first wiring layer. The input wiring line 24 disposed in the second wiring layer extends in the y-direction from a region where the input wiring line 24 overlaps the row of input capacitors 20C and reaches the matching circuit 52 after passing through a region where the input wiring line 24 overlaps each of the bias wiring line 23 and the base ballast resistor 20R with no other wiring layer interposed between.

The first individual wiring line 25a connecting the emitter of the corresponding one of the common-base transistors 30Qs and the first common wiring line 25 is disposed in the first wiring layer. The resistor 30Rs and wiring that connect the base of the corresponding one of the common-base transistors 30Qs and the second common wiring line 26 are disposed in the first wiring layer.

The common-base transistors 30Qs are positioned to overlap the ground pad 40.

Effects of the modification of the third embodiment illustrated in FIG. 13 will now be described.

According to the modification of the third embodiment illustrated in FIG. 13, the common-base transistors 30Qs are positioned to overlap the ground pad 40. This limits an increase in the area required to provide the common-base transistors 30Qs and other components.

According to the third embodiment (FIG. 11), the row of common-base transistors 30Qs, the second common wiring line 26, the first common wiring line 25, and the bias wiring line 23 are disposed between the row of input capacitors 20C and the matching circuit 52. In contrast, according to the modification of the third embodiment illustrated in FIG. 13, the row of common-base transistors 30Qs, the second common wiring line 26, and the first common wiring line 25 are not disposed between the row of input capacitors 20C and the matching circuit 52. This reduces the dimension in the y-direction of a portion of the input wiring line 24, the portion connecting the matching circuit 52 with a portion of the input wiring line 24 that serves as the upper electrode of the input capacitor 20C and that extends in the x-direction. Thus, the length of the wiring from the matching circuit 52 to the input capacitor 20C decreases. This helps to limit an increase in a parasitic inductance generated due to the wiring.

According to the modification of the third embodiment illustrated in FIG. 13, a portion of the input wiring line 24 that connects the matching circuit 52 with a portion where the input wiring line 24 overlaps the input capacitor 20C is positioned to overlap the bias wiring line 23 and the base ballast resistor 20R. This makes it possible to reduce the dimension of the Doherty amplifier in the x-direction, as with the modification of the third embodiment illustrated in FIG. 12.

### (Fourth Embodiment)

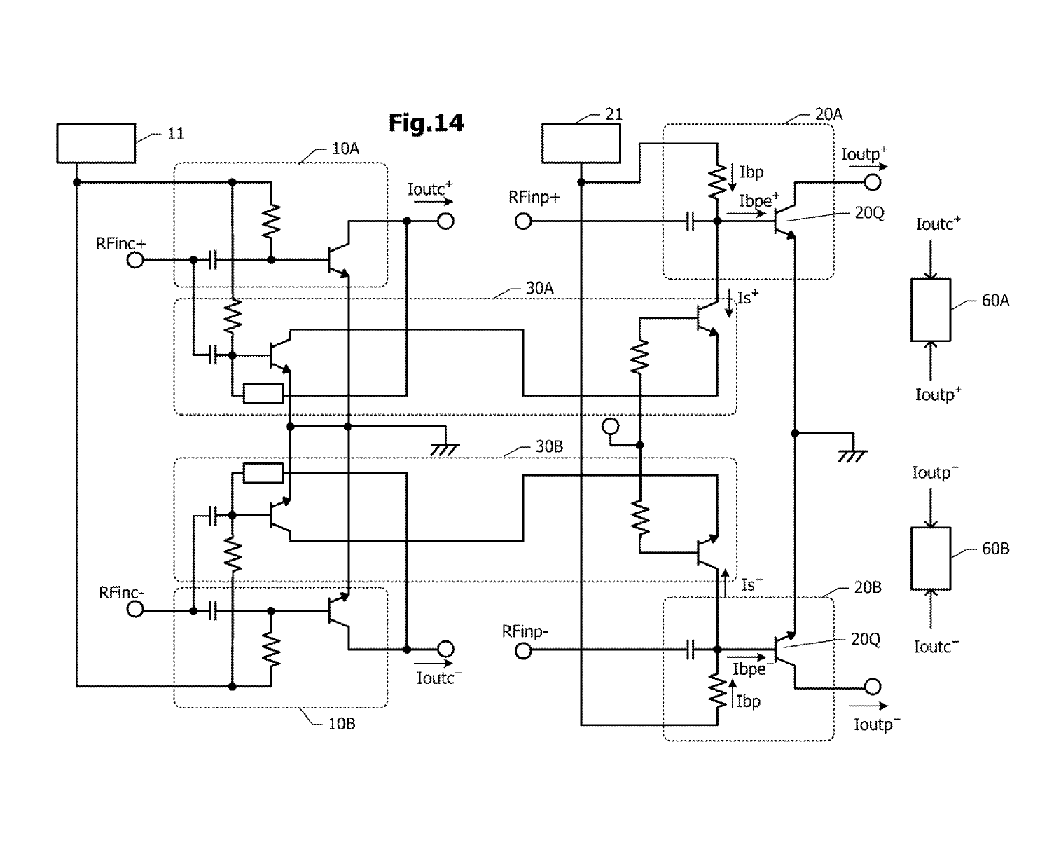

A Doherty amplifier according to a fourth embodiment will now be described with reference to FIG. 14. Features similar to those of the Doherty amplifier according to the second embodiment described above with reference to FIGS. 5 to 9 will not be described below in further detail.

FIG. 14 is an equivalent circuit diagram of the Doherty amplifier according to the fourth embodiment. Although the Doherty amplifier according to the second embodiment amplifies a single-ended signal, the Doherty amplifier according to the fourth embodiment amplifies a differential signal.

The Doherty amplifier according to the fourth embodiment includes a first carrier amplifier 10A, a first peak amplifier 20A, a second carrier amplifier 10B, and a second peak amplifier 20B. The first carrier amplifier 10A and the second carrier amplifier 10B constitute a differential amplifier, and the first peak amplifier 20A and the second peak amplifier 20B constitute a differential amplifier.

The first carrier amplifier 10A and the second carrier amplifier 10B are identical in configuration to the carrier amplifier 10 (FIG. 6) of the Doherty amplifier according to the second embodiment. The first peak amplifier 20A and the second peak amplifier 20B are identical in configuration to the peak amplifier 20 (FIG. 6) of the Doherty amplifier according to the second embodiment.

A carrier-amplifier non-inverting input signal RFinc⁺ and a carrier-amplifier inverting input signal RFinc⁻ are inputted to the first carrier amplifier 10A and the second carrier amplifier 10B, respectively. A peak-amplifier non-inverting input signal RFinp⁺ and a peak-amplifier inverting input signal RFinp⁻ are inputted to the first peak amplifier 20A and the second peak amplifier 20B, respectively.

The carrier-amplifier non-inverting input signal RFinc⁺ is delayed by 90 degrees in phase relative to the peak-amplifier non-inverting input signal RFinp⁺. The carrier-amplifier inverting input signal RFinc⁻is inverted in phase relative to the carrier-amplifier non-inverting input signal RFinc⁺. Likewise, the peak-amplifier inverting input signal RFinp⁻ is inverted in phase relative to the peak-amplifier non-inverting input signal RFinp⁺.

The output current Ioutc⁺ from the first carrier amplifier 10A and the output current Ioutp⁺ from the first peak amplifier 20A are inputted to a first combiner 60A. The output current Ioutc- from the second carrier amplifier 10B and the output current Ioutp- from the second peak amplifier 20B are inputted to a second combiner 60B.

A first draw-off circuit 30A is connected to the input node and the output node of the first carrier amplifier 10A and generates a draw-off current Is⁺ for a non-inverting signal. The draw-off current Is⁺ for a non-inverting signal is drawn off from the bias current Ibp supplied to the first peak amplifier 20A, and an effective bias current Ibpe⁺, which is the remaining bias current, is supplied to the base of the peak-amplifier transistor 20Q of the first peak amplifier 20A.

Likewise, a second draw-off circuit 30B is connected to the input node and the output node of the second carrier amplifier 10B and generates a draw-off current Is⁻ for an inverting signal. The draw-off current Is⁻for an inverting signal is drawn off from the bias current Ibp supplied to the second peak amplifier 20B, and an effective bias current Ibpe⁻, which is the remaining bias current, is supplied to the base of the peak-amplifier transistor 20Q of the second peak amplifier 20B.

Effects of the fourth embodiment will now be described.

According to the fourth embodiment, each of the carrier amplifier 10 (FIG. 1) and the peak amplifier 20 (FIG. 1) is a differential amplifier. This configuration provides a low-noise Doherty amplifier. Further, according to the fourth embodiment, the first draw-off circuit 30A adjusts the bias current supplied to the first peak amplifier 20A, based on the radio frequency current of the carrier-amplifier non-inverting input signal RFinc⁺ inputted to the input node of the first carrier amplifier 10A, and the second draw-off circuit 30B adjusts the bias current supplied to the second peak amplifier 20B, based on the radio frequency current of the carrier-amplifier inverting input signal RFinc⁻ inputted to the input node of the second carrier amplifier 10B. This configuration makes it possible to mitigate PAE degradation in amplifying a high-PAPR signal, as with the first embodiment described above with reference to FIGS. 1 to 4.

Further, according to the fourth embodiment, the first draw-off circuit 30A adjusts the bias current supplied to the first peak amplifier 20A, based on the radio frequency current of the output signal RFoutc⁺ outputted from the output node of the first carrier amplifier 10A, and the second draw-off circuit 30B adjusts the bias current supplied to the second peak amplifier 20B, based on the radio frequency current of the output signal RFoutc- outputted from the output node of the second carrier amplifier 10B. This makes it possible to ensure sufficient flatness of the gain of the Doherty amplifier even when the load impedance ZL varies, as with the second embodiment described above with reference to FIGS. 5 to 9.

It is needless to mention that the embodiments described above are illustrative only, and features described in different embodiments may be partially substituted for or combined with each other. The same or similar operational effects provided by the same or similar features in a plurality of embodiments are not mentioned for each individual embodiment. Further, the present disclosure is not limited to the above-mentioned embodiments. For example, it will be obvious to those skilled in the art that various modifications, improvements, combinations, and the like are possible.

10 carrier amplifier

10A first carrier amplifier

10B second carrier amplifier

10C input capacitor

10Q carrier-amplifier transistor

10R base ballast resistor

11 carrier-amplifier bias circuit

20 peak amplifier

20a cell of peak amplifier

20A first peak amplifier

20B second peak amplifier

20C input capacitor

20Q peak-amplifier transistor

20R base ballast resistor

21 peak-amplifier bias circuit

21C capacitor

21D diode circuit

21Q emitter-follower transistor

21R resistor

22 collector wiring line

22a individual collector wiring line

23 bias wiring line

23a individual bias wiring line

23b input-capacitor lower wiring line

24 input wiring line

24A second-layer input wiring line

24B third-layer input wiring line

25 first common wiring line

25a first individual wiring line

26 second common wiring line

30 draw-off circuit

30A first draw-off circuit

30B second draw-off circuit

30C capacitor

30CC constant current source

30Qd common-emitter transistor

30Qs common-base transistor

30Rd, 30Rs resistor

35 attenuator

40 ground pad in second layer

40A conductor pattern in second layer

40B ground pad in third layer

50 divider

51 matched termination resistor

52 matching circuit

60 combiner

60A first combiner

60B second combiner

61 90° phase shifter

70 impedance matching circuit

71 load

1. A Doherty amplifier comprising:
a carrier amplifier;
a peak amplifier;
a carrier-amplifier bias circuit configured to supply a carrier bias to the carrier amplifier;
a peak-amplifier bias circuit configured to supply a peak bias to the peak amplifier; and
a draw-off circuit configured to draw off a portion of a bias current of the peak bias,
wherein the draw-off circuit comprises a cascode circuit in which a common-base transistor and a common-emitter transistor are cascode-connected,
wherein a collector of the common-base transistor is connected to the peak amplifier, and
wherein a base of the common-emitter transistor is connected to an input node of the carrier amplifier.

2. The Doherty amplifier according to claim 1, wherein a current that flows in the cascode circuit is drawn off from the bias current of the peak bias.

3. The Doherty amplifier according to claim 1, wherein the base of the common-emitter transistor is further connected to an output node of the carrier amplifier.

4. The Doherty amplifier according to claim 3, wherein the draw-off circuit comprises an attenuator configured to make a first radio frequency current smaller in amplitude than a second radio frequency current, the first radio frequency current being a current that is a portion of an output current outputted from the output node of the carrier amplifier and that is inputted to the base of the common-emitter transistor, the second radio frequency current being a current that is a portion of an input current inputted to the input node of the carrier amplifier and that is inputted to the base of the common-emitter transistor.

5. The Doherty amplifier according to claim 1,
wherein the carrier amplifier comprises a first carrier amplifier and a second carrier amplifier that constitute a carrier differential amplifier,
wherein the peak amplifier comprises a first peak amplifier and a second peak amplifier that constitute a peak differential amplifier,
wherein the peak-amplifier bias circuit is configured to supply a second peak bias current to the second peak amplifier and to supply a first peak bias current to the first peak amplifier, and
wherein the draw-off circuit comprises:
a first draw-off circuit connected to an input node of the first carrier amplifier and configured to draw off a portion of the first peak bias current supplied to the first peak amplifier, and
a second draw-off circuit connected to an input node of the second carrier amplifier and configured to draw off a portion of the second peak bias current supplied to the second peak amplifier.

6. The Doherty amplifier according to claim 5, wherein the first draw-off circuit is further connected to an output node of the first carrier amplifier, and the second draw-off circuit is further connected to an output node of the second carrier amplifier.

7. The Doherty amplifier according to claim 1,
wherein the peak amplifier comprises a plurality of cells connected in parallel to each other,
wherein each of the plurality of cells comprises:
a peak-amplifier transistor; and
a base ballast resistor in a path through which the peak bias is supplied from the peak-amplifier bias circuit to a base of the peak-amplifier transistor, and
wherein the common-base transistor of the draw-off circuit is provided for each of the plurality of cells.

8. A Doherty amplifier comprising:
a carrier amplifier;
a peak amplifier;
a carrier-amplifier bias circuit configured to supply a carrier bias to the carrier amplifier;
a peak-amplifier bias circuit configured to supply a peak bias to the peak amplifier; and
a draw-off circuit configured to draw off, from a bias current of the peak bias, a current that is dependent on an amplitude of an input current inputted to the carrier amplifier.

9. The Doherty amplifier according to claim 8, wherein the draw-off circuit is further configured to draw off, from the bias current of the peak bias, the current that is dependent on the amplitude of the input current inputted to the carrier amplifier and on an amplitude of an output current.
